(19) United States
(12) Patent Application Publication
(10) Pub. No.: US 2025/0180616 A1
(43) Pub. Date: Jun. 5, 2025

(54) STABLE RADIO FREQUENCY (RF) AMPLITUDE DETECTOR

(71) Applicant: Quantinuum LLC, Broomfield, CO (US)

(72) Inventors: Carl Johann Sauer, Broomfield, CO (US); Leonardo Ascarrunz, Broomfield, CO (US)

(21) Appl. No.: 18/965,387

(22) Filed: Dec. 2, 2024

Related U.S. Application Data
(60) Provisional application No. 63/605,784, filed on Dec. 4, 2023.

(51) Int. Cl. G01R 29/08; H03K 5/01

(52) U.S. Cl. CPC G01R 29/0878; H03K 5/01

(57) ABSTRACT

Various examples in accordance with the present disclosure provide a stable RF amplitude detector. Some embodiments include a diode bridge circuit comprising a plurality of diodes, wherein at least a portion of the plurality of diodes are biased together and configured to rectify a positive peak of an RF input and a negative peak of the RF input. Some embodiments include a differential amplifier circuit comprising a plurality of differential amplifiers. The differential amplifier circuit may be configured to: (a) compare the positive peak of the RF input rectified by the diode bridge circuit to a positive DC setpoint input, (b) compare the negative peak of the RF input rectified by the diode bridge circuit to a negative DC setpoint input, and (c) output an error value.

### CROSS-REFERENCE TO RELATED APPLICATIONS

This application claims priority to U.S. Provisional Patent Application No. 63/605,784 filed on Dec. 4, 2023, which is incorporated herein by reference in its entirety.

### FIELD OF THE INVENTION

Example embodiments of the present disclosure relate generally to an RF synthesizer amplifier and, more particularly, to a stable RF amplitude detector for an RF synthesizer.

### BACKGROUND

Applicant has identified many technical challenges and difficulties associated with RF synthesizers and RF amplitude detectors. Through applied effort, ingenuity, and innovation, Applicant has solved many of these identified problems by developing the embodiments of the present disclosure, which are described in detail below.

### BRIEF SUMMARY

Various embodiments described herein relate to RF synthesizer, and more particularly to RF amplitude detector for an RF synthesizer.

In accordance with one aspect of the present disclosure, a RF amplitude detector is provided. In some embodiments, the RF amplitude detector comprises a diode bridge circuit comprising a plurality of diodes, wherein at least a portion of the plurality of diodes are biased together and configured to rectify a positive peak of an RF input and a negative peak of the RF input; and a differential amplifier circuit comprising a plurality of differential amplifiers, the differential amplifier circuit configured to: (a) compare the positive peak of the RF input rectified by the diode bridge circuit to a positive DC setpoint input, (b) compare the negative peak of the RF input rectified by the diode bridge circuit to a negative DC setpoint input, and (c) output an error value.

In some embodiments, the diode bridge circuit comprises a first diode having a negative terminal coupled to the RF input via a transformer and a positive terminal coupled to a first amplifier of the differential amplifier circuit; a second diode having a positive terminal coupled to the RF input via the transformer and a negative terminal coupled to a second amplifier of the differential amplifier; a third diode in a path of the negative DC setpoint input; and a fourth diode in a path of the positive DC setpoint input.

In some embodiments, the negative terminal of the first diode is coupled to the positive terminal of the second diode.

In some embodiments, the example RF amplitude detector further comprises an inverter amplifier configured to output the negative DC setpoint input based on the positive DC setpoint input.

In some embodiments, a first resistor is coupled between the negative terminal of the first diode and the first amplifier; a second resistor is coupled between the negative terminal of the second diode and the second amplifier; a third resistor is coupled between a positive terminal of the third diode and a third amplifier; and a fourth resistor is coupled between a negative terminal of the fourth diode and the fourth resistor.

In some embodiments, the first resistor and the third resistor have a first predetermined resistance ratio; and the second resistor and the fourth resistor have a second predetermined resistance ratio.

In some embodiments, the first predetermined resistance ratio and the second predetermined resistance ratio are the same.

In some embodiments, the first resistor and the second resistor have substantially the same resistance value.

In some embodiments, the third resistor and fourth resistor have substantially the same resistance value.

In some embodiments, at least a portion of the RF amplitude detector is temperature controlled.

In accordance with another aspect of the present disclosure, an RF synthesizer is provided. In some embodiments, the RF synthesizer comprises an RF amplitude detector, the RF amplitude detector comprising: a diode bridge circuit comprising a plurality of diodes, wherein at least a portion of the plurality of diodes are biased together and configured to rectify a positive peak of an RF input and a negative peak of the RF input; and a differential amplifier circuit comprising a plurality of differential amplifiers, the differential amplifier circuit configured to: (a) compare the positive peak of the RF input rectified by the diode bridge circuit to a positive DC setpoint input, (b) compare the negative peak of the RF input rectified by the diode bridge circuit to a negative DC setpoint input, and (c) output an error value.

In some embodiments, the diode bridge circuit comprises a first diode having a negative terminal coupled to the RF input via a transformer and a positive terminal coupled to a first amplifier of the differential amplifier circuit; a second diode having a positive terminal coupled to the RF input via the transformer and a negative terminal coupled to a second amplifier of the differential amplifier; a third diode in a path of the negative DC setpoint input; and a fourth diode in a path of the positive DC setpoint input.

In some embodiments, the negative terminal of the first diode is coupled to the positive terminal of the second diode.

In some embodiments, the RF amplitude detector further comprises an inverter amplifier configured to output the negative DC setpoint input based on the positive Dc setpoint input.

In some embodiments, a first resistor is coupled between the negative terminal of the first diode and the first amplifier; a second resistor is coupled between the negative terminal of the second diode and the second amplifier; a third resistor is coupled between a positive terminal of the third diode and a third amplifier; and a fourth resistor is coupled between a negative terminal of the fourth diode and the fourth resistor.

In some embodiments, the first resistor and the third resistor have a first predetermined resistance ratio; and the second resistor and the fourth resistor have a second predetermined resistance ratio.

In some embodiments, the first predetermined resistance ratio and the second predetermined resistance ratio are the same.

In some embodiments, the first resistor and the second resistor have substantially the same resistance value.

In some embodiments, the third resistor and fourth resistor have substantially the same resistance value.

In some embodiments, at least a portion of the RF amplitude detector is temperature controlled.

The foregoing illustrative summary, as well as other exemplary objectives and/or advantages of the disclosure, and the manner in which the same are accomplished, are further explained in the following detailed description and its accompanying drawings.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 is a schematic diagram illustrating an example quantum computing system within which an RF synthesizer comprising an RF amplitude detector may be utilized in accordance with at least one example embodiment of the present disclosure.

FIG. 2 illustrates a block diagram of an example RF synthesizer within which an example RF amplitude detector may be utilized in accordance with at least one example embodiment of the present disclosure.

FIGS. 3A-B illustrates a circuit diagram of an example RF amplitude detector in accordance with at least one example embodiment of the present disclosure.

FIG. 4 provides a flowchart depicting operations of an example RF amplitude detector in accordance with at least one example embodiment of the present disclosure.

FIG. 5 provides a schematic diagram of an example controller of a quantum computer that may be used in accordance with an example embodiment.

FIG. 6 provides a schematic diagram of an example computing entity of a quantum computer system that may be used in accordance with an example embodiment.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

As used herein, the term “or” is used in both the alternative and conjunctive sense, unless otherwise indicated. The terms “illustrative” and “example” are used to be examples with no indication of quality level. Terms such as “computing,” “determining,” “generating,” and/or similar words are used herein interchangeably to refer to the creation, modification, or identification of data. Further, “based on,” “based on in part on,” “based at least on,” “based upon,” and/or similar words are used herein interchangeably in an open-ended manner such that they do not indicate being based only on or based solely on the referenced element or elements unless so indicated. Like numbers refer to like elements throughout.

Various applications, systems, and/or the like utilize an RF synthesizer. For example, an RF synthesizer may be utilized in a quantum computing system comprising an atomic object confinement apparatus to generate RF signals for the atomic object confinement apparatus. In some embodiments, the atomic object confinement apparatus is an ion trap (e.g., a surface ion trap, Paul trap, and/or the like). In this regard, an RF synthesizer may be utilized to generate RF signals for the ion trap. An example ion trap may comprise one or more radio frequency (RF) electrodes or rails. The RF electrodes and/or rails may be fed through one or more feed ports such that the current spreads (and dissipates) across the trap through the RF electrodes and/or rails.

The application of an RF current or voltage to the RF electrodes and/or rails may be configured to perform various functions. For example, the application of an RF current or voltage to the RF electrodes may be configured generate one or more trapping regions within the ion trap for trapping manipulatable objects such as (e.g., objects that can be manipulated and/or trapped by the ion trap such as ions, multipole atoms or molecules, charged molecules, charged particles, and/or the like).

In some applications a stable RF amplitude control is required. As one example, a stable RF amplitude control is required for radial gates. Conventional solutions are deficient with regard to providing stable RF amplitude control. Conventional solutions utilize diodes and diode configuration that are generally unstable. For example, conventional solutions have temperature coefficients on the order of millivolts per degree Celsius for the diode drop.

Embodiments of the present disclosure address the above-mentioned challenges and difficulties, as well as other challenges and difficulties associated with RF detectors and RF synthesizers. Embodiments of the present disclosure provide a stable RF amplitude detector having a diode bridge configuration at the input stage that enables a stable RF amplitude control. Some embodiments include a diode bridge that is balanced with itself in that the diode configuration includes a DC (direct current) setpoint input that converts to a negative DC setpoint. Some embodiments, include a diode bridge configuration defining a positive branch and a negative branch that are coupled to a difference amplifier circuit. In some embodiments, the diode bridge rectifies the positive peak of the RF power and the negative peak of the RF power and then compares positive peak of the RF power and the negative peak of the RF power with the positive setpoint input and the negative setpoint input. In some embodiments, a portion of the diodes are biased together, so the current is identical through the diodes for the RF power level. In some embodiments, the difference amplifier circuit sums and/or subtracts the setpoints for the positive leg and the negative leg to output the error. In some embodiments, the circuit is temperature controlled to reduce the thermal drift of the circuit. Accordingly, embodiments, of the present disclosure provide an RF amplitude detector that allows long term stability for RF amplitude measurement to be achieved and Embodiments of and effectively cancels out the temperature coefficients of the diodes of the RF amplitude detector.

### Example Quantum Computing System Comprising an Atomic Object Confinement Apparatus

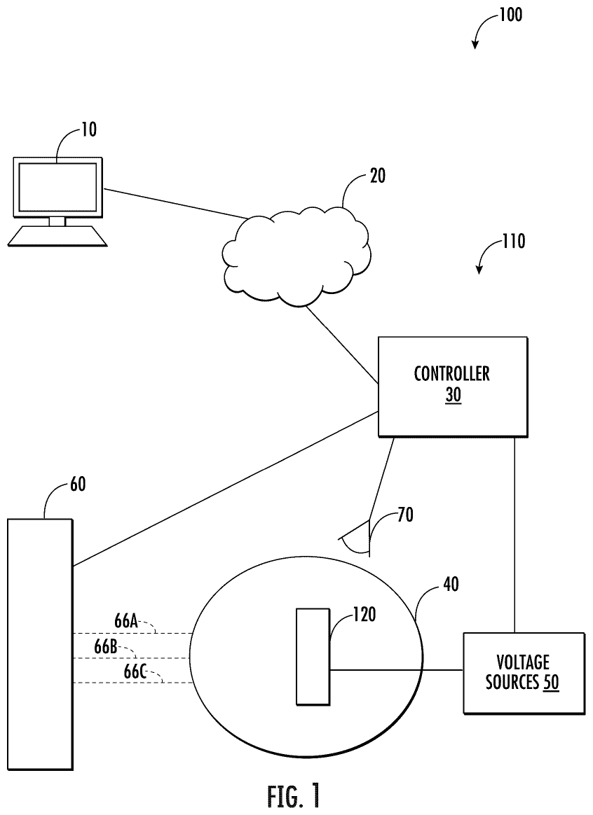

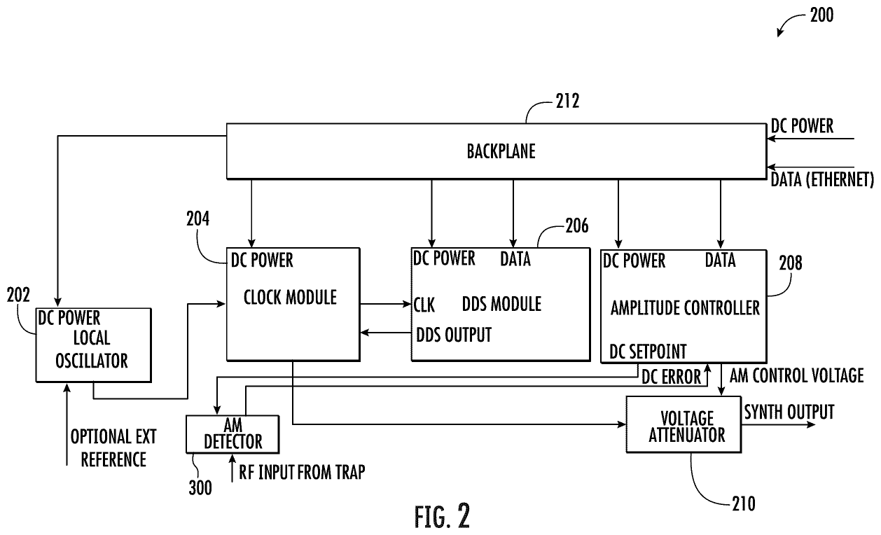

FIG. 1 provides a schematic diagram of an example quantum computing system 100 comprising an atomic object confinement apparatus 120 (e.g., an ion trap and/or the like), in accordance with an example embodiment. In various embodiments, a plurality of signal manipulation elements is formed and/or disposed on a surface of the atomic object confinement apparatus 120. In various embodiments, at least a portion of the signal manipulation elements formed and/or disposed on the surface of the atomic object confinement apparatus 120 are configured to be induced to emit an action signal toward and/or focused onto a respective atomic object position responsive to an incoming signal being incident thereon. The incoming signal may be at least a portion of a manipulation signal generated by the manipulation source of the quantum computer 110.

In various embodiments, the quantum computing system 100 comprises a computing entity 10 and a quantum computer 110. In various embodiments, the quantum computer 110 comprises a controller 30, a cryogenic and/or vacuum chamber 40 enclosing a confinement apparatus 120 (e.g., an ion trap). In various embodiments, the cryogenic and/or vacuum chamber 40 is a temperature and/or pressure-controlled chamber. For example, the quantum computing system 100 may comprise vacuum and/or temperature control components that are operatively coupled to the cryogenic and/or vacuum chamber 40.

In an example embodiment, the manipulation signals generated by the manipulation sources 60 are provided to the interior of the cryogenic and/or vacuum chamber 40 (e.g., where the atomic object confinement apparatus 120 is located via corresponding optical paths (e.g., 66A, 66B, 66C). In various embodiments, the optical paths are defined at least in part by one or more components and/or elements of the signal management system.

In an example embodiment, the one or more manipulation sources 60 may comprise one or more lasers (e.g., optical lasers, microwave sources, and/or the like). In various embodiments, each manipulation source is configured to generate a manipulation signal having a respective characteristic wavelength in the microwave, infrared, visible, or ultraviolet portion of the electromagnetic spectrum. In various embodiments, the one or more manipulation sources 60 are configured to manipulate and/or cause a controlled quantum state evolution of the one or more atomic objects within the confinement apparatus 120. For example, in an example embodiment, wherein the one or more manipulation sources 60 comprise one or more lasers, the lasers may provide one or more laser beams to atomic objects trapped by the confinement apparatus 120 within the cryogenic and/or vacuum chamber 40.

For example, a manipulation source 60 generates a manipulation signal that is provided as an incoming signal to an appropriate signal manipulation element of the signal management system. The incoming signal being incident on the signal manipulation element, for example a metamaterial array, induces the plurality of metamaterial structures of the metamaterial array to emit an action signal directed toward and/or focused at a corresponding atomic object position of the atomic object confinement apparatus. For example, the manipulation sources 60 may be configured to generate one or more beams that may be used to initialize an atomic object into a state of a qubit space such that the atomic object may be used as a qubit of the confined atomic object quantum computer, perform one or more gates on one or more qubits of the confined atomic object quantum computer, read and/or determine a state of one or more qubits of the confined atomic object quantum computer, and/or the like.

In various embodiments, the quantum computer 110 comprise an optics collection system 70 configured to collect and/or detect photons generated by qubits (e.g., during reading procedures). The optics collection system 70 may comprise one or more optical elements (e.g., lenses, mirrors, waveguides, fiber optics cables, and/or the like) and one or more photodetectors. In various embodiments, the photodetectors may be photodiodes, photomultipliers, charge-coupled device (CCD) sensors, complementary metal oxide semiconductor (CMOS) sensors, Micro-Electro-Mechanical Systems (MEMS) sensors, and/or other photodetectors that are sensitive to light at an expected fluorescence wavelength of the qubits of the quantum computer. In various embodiments, the detectors may be in electronic communication with the controller 30 via one or more A/D converters and/or the like. For example, an atomic object being read and/or having its quantum state determined may emit an emitted signal, at least a portion of which is incident on a collection array of the signal management system. The emitted signal being incident on the collection array induces the plurality of metamaterial structures of the collection array to emit a detecting signal directed toward and/or focused at collection optics of the atomic object confinement apparatus. The collection optics are configured to provide the collection signal to a photodetector.

In various embodiments, the quantum computer 110 comprises one or more voltage sources 50. For example, the voltage sources 50 may comprise a plurality of voltage drivers and/or voltage sources and/or at least one RF driver and/or voltage source. The voltage sources 50 may be electrically coupled to the corresponding electrode elements (e.g., electrodes) of the confinement apparatus, in an example embodiment.

In various embodiments, a computing entity 10 is configured to allow a user to provide input to the quantum computer 110 (e.g., via a user interface of the computing entity 10) and receive, view, and/or the like output from the quantum computer 110. The computing entity 10 may be in communication with the controller 30 of the quantum computer 110 via one or more wired or wireless networks 20 and/or via direct wired and/or wireless communications. In an example embodiment, the computing entity 10 may translate, configure, format, and/or the like information/data, quantum computing algorithms and/or circuits, and/or the like into a computing language, executable instructions, command sets, and/or the like that the controller 30 can understand and/or implement.

In various embodiments, the controller 30 is configured to control and/or in electrical communication with the voltage sources 50, cryogenic system and/or vacuum system controlling the temperature and/or pressure within the cryogenic and/or vacuum chamber 40, manipulation sources, and/or other systems controlling various environmental conditions (e.g., temperature, pressure, and/or the like) within the cryogenic and/or vacuum chamber 40 and/or configured to manipulate and/or cause a controlled evolution of quantum states of one or more quantum objects within the confinement apparatus. For example, the controller 30 may cause a reading procedure comprising coherent shelving to be performed, possibly as part of executing a quantum circuit and/or algorithm. In various embodiments, the atomic objects confined within the confinement apparatus are used as qubits of the quantum computer 110.

### Example Atomic Object Confinement Apparatus

In various embodiments, the atomic object confinement apparatus comprises a plurality of electrodes that are configured to generate a confining potential. For example, the controller 30 may control the voltage sources 50 to provide electrical signals to the electrodes of the atomic object confinement apparatus such that the electrodes generate a confining potential. The confining potential is configured to confine a plurality of atomic objects within a confinement volume defined by the atomic object confinement apparatus. For example, in an example embodiment, the atomic object confinement apparatus is a surface ion trap and the confinement volume is a volume located proximate the surface of the surface ion trap. In various embodiments, the electrodes and/or confining potential are configured to define a plurality of atomic object positions within the confinement volume.

In various embodiments, the atomic object positions are disposed in a one-dimensional or two-dimensional lay out. For example, in an example embodiment, the atomic object positions are disposed along an axis of a linear atomic object confinement apparatus. In another example embodiment, the atomic object positions are disposed in a two-dimensional array or layout defined by a two-dimensional atomic object confinement apparatus.

In various embodiments, the confining potential evolves with time, based on the electrical signals provided to the electrodes by the voltage sources 50. The evolving of the confining potential may be configured to cause one or more atomic objects to move from respective first atomic object positions to respective second atomic object positions. An example two-dimensional atomic object confinement apparatus 120, for example, may comprise sequences of electrodes that are separated by a spacing factor. In an example embodiment, the spacing factor is in a range between 500 μm and 1000 μm (e.g., approximately 750 μm). The sequences of electrodes may define a plurality of atomic object positions. In various embodiments, an atomic object position is a volume corresponding to a portion of an atomic object path where the electrodes are configured to maintain an atomic object (e.g., as part of an atomic object crystal) and/or a pair or set of atomic objects (e.g., for performing two or more qubit gates) for the performance of a function of the quantum computer and/or to store one or more atomic objects during the performance of functions of the quantum computer on other atomic objects located at other atomic positions.

In various embodiments, the voltage sources 50 provide electrical signals to the potential generating elements (e.g., electrodes) of the confinement apparatus 120, such that a confining potential is formed. Based on the contours and time evolution of the confining potential one or more atomic objects are confined at respective atomic object positions, moved between atomic object positions and/or the like. When an atomic object is located at an atomic object position, one or more functions (e.g., quantum computing functions) may be performed on the atomic object. An example function that may be performed on an atomic object is photoionization of the atomic object. For example, a manipulation signal may be applied to the atomic object to photo ionize the atomic object.

Another example function that may be performed on an atomic object is state preparation of the atomic object. For example, one or more manipulation signals may be applied to the atomic object to prepare the atomic object in a particular quantum state. For example, the particular quantum state may be a state within a defined qubit space used by the quantum computer such that the atomic object may be used as a qubit of the quantum computer.

Another example function that may be performed on an atomic object is reading a quantum state of the atomic object. For example, a manipulation signal (e.g., a reading signal) may be applied to the atomic object. When the atomic object's wave function collapses into a first state of the qubit space, the atomic object will fluoresce in response to the reading signal being applied thereto. When the atomic object's wave function collapses into a second state of the qubit space, the atomic object will not fluoresce in response to the reading signal being applied thereto.

Another example function that may be performed on an atomic object is cooling the atomic object or an atomic object crystal comprising the atomic object. An atomic object crystal is a pair or set of atomic objects where one of the atomic objects of the atomic object crystal is qubit atomic object used as a qubit of the quantum computer and the one or more other atomic objects of the atomic object crystal are used to perform sympathetic cooling of the qubit atomic object. For example, a manipulation signal (e.g., a cooling signal or a sympathetic cooling signal) may be applied to the atomic object or atomic object crystal to cause the (qubit) atomic object to be cooled (e.g., reduce the vibrational and/or other kinetic energy of the (qubit) atomic object).

Another example function that may be performed on an atomic object is shelving the atomic object. In various embodiments, atomic objects in the second state of the qubit space may be shelved during the performance of a reading function. For example, a shelving operation may comprise causing the quantum state of an atomic object in the second state of the qubit space to evolve to an at least meta-stable state outside of the qubit space while a reading operation is performed. In various embodiments, the shelving of an atomic object is performed by applying one or more manipulation signals to the atomic object to cause the atomic object's quantum state to evolve to an at least meta-stable state outside of the qubit space when the atomic object is in the second state of the qubit space.

Another example function that may be performed on an atomic object is (optical) repumping of the atomic object. In various embodiments, repumping of the atomic object comprises applying one or more manipulation signals to the atomic object to cause the quantum state of the atomic object to evolve to an excited state.

Another example function that may be performed on an atomic object is performing a single qubit gate on the atomic object. For example, one or more manipulation signals may be applied to the atomic object to perform a single qubit quantum gate on the atomic object.

Another example function that may be performed on an atomic object is performing a two-qubit gate on the atomic object. For example, one or more manipulation signals may be applied to a pair or set of atomic objects that includes the atomic object to perform a two qubit (or three, four, or more) quantum gate on the atomic object and the at least one other atomic object. Another example function that may be performed on an atomic object is performing a radial gate on the atomic objects.

In various embodiments, the atomic object confinement apparatus 120 comprises one or more signal manipulation elements. In various embodiments, the manipulation signals are provided transverse to a plane defined by a surface of the atomic object confinement apparatus 120 such that the manipulation signals are incident on corresponding signal manipulation elements. Each signal manipulation element is configured to, responsive to an incoming manipulation signal being incident thereon, induce an action signal that is emitted such that the action signal is directed to a respective atomic object position of the atomic object confinement apparatus 120 that corresponds to the signal manipulation element. The action signal is an appropriate signal (e.g., having an appropriate wavelength, polarization, amplitude, and/or the like) for causing the corresponding function to be performed responsive to the action signal (and possibly application of other action signals, magnetic fields, and/or the like) being incident on an atomic object (or set of atomic objects) at the corresponding atomic object position.

### Example RF Synthesizer Comprising an RF Amplitude Detector

FIG. 2 illustrates a block diagram of an example RF synthesizer 200 within which an example RF amplitude detector may be utilized in accordance with at least one example embodiment of the present disclosure. The RF synthesizer 200 comprises a local oscillator 202, a clock module 204, a direct digital synthesis (DDS) module 206, an amplitude controller 208, a voltage attenuator 210, a backplane 212, and a stable RF amplitude detector 300. The local oscillator 202 may be configured to generate a primary reference frequency that is fed as input into the clock module 204 to condition the primary reference frequency. In some embodiments, the clock module 204 is configured such that it provides low noise phase. The conditioned primary reference frequency is fed into the DDS module 206. The DDS module 206 may be configured to output an arbitrary frequency. The DDS output frequency from the DDS module 206 is provided as input to the voltage attenuator 210 (e.g., via the clock module 204). As shown in FIG. 2, the voltage attenuator 210 may be controlled by the amplitude controller 208 (e.g., an analog feedback loop). The RF amplitude detector 300 may receive trap input frequency (e.g., RF input from the ion trap) and DC setpoint as inputs. The amplitude controller 208 may be configured to provide the DC setpoint input to the RF amplitude detector 300, receive the output of the RF amplitude detector 300 (e.g., DC error), and control the voltage with the voltage attenuator 210, which sets the amplitude. By way of example, the RF synthesizer 200 may be configured to be integrated or otherwise work with a trap resonator pickoff for the feedback path.

### Example RF Amplitude Detector

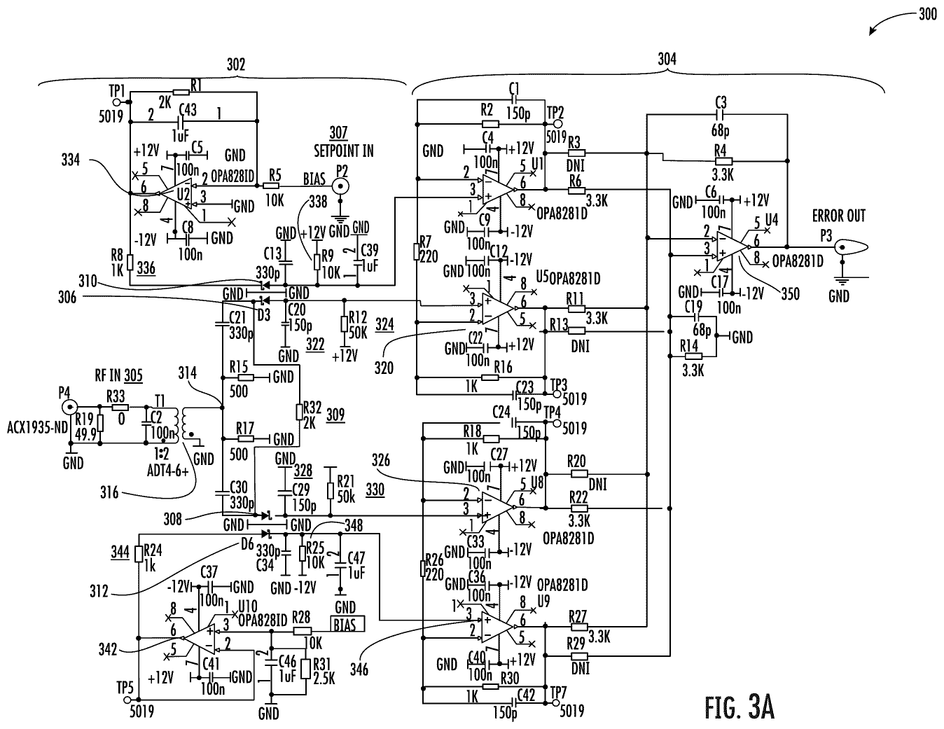

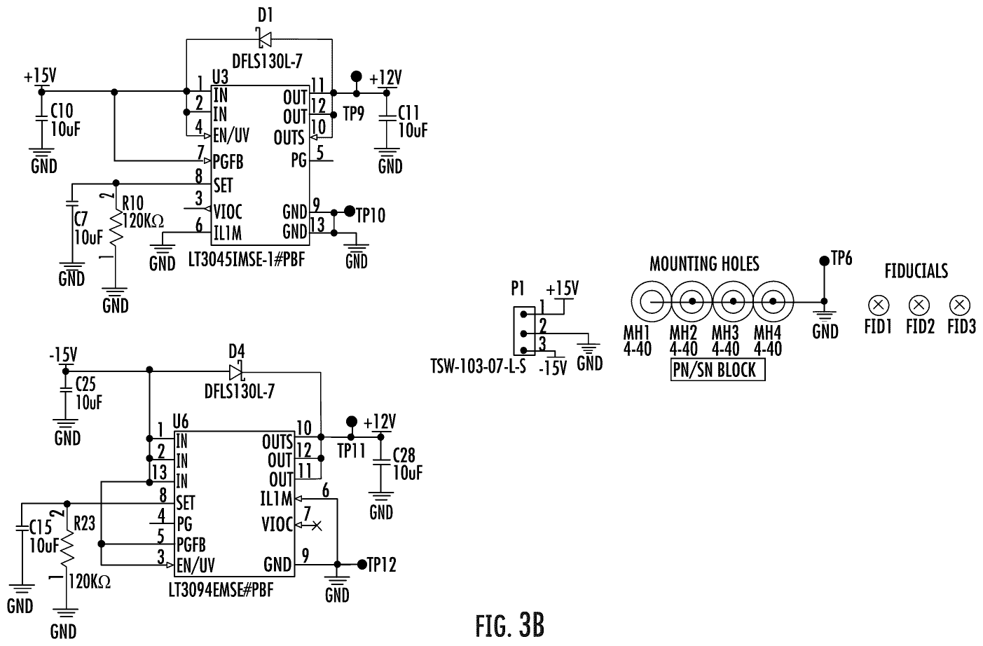

FIG. 3A, illustrates an example RF amplitude detector 300 in accordance with at least one embodiment of the present disclosure. Specifically, FIG. 3A illustrates an example stable RF amplitude detector in accordance with at least one embodiment of the present disclosure. The depiction of the example RF amplitude detector 300 is not intended to limit or otherwise confine the embodiments described and contemplated herein to any particular configuration of elements or specifications thereof, nor is it intended to exclude any alternative configurations that can be used in connection with embodiments of the present disclosure. In some embodiments, the example RF amplitude detector comprises a diode bridge circuit 302 and differential amplifier circuit 304 coupled to the diode bridge circuit 302. The diode bridge circuit 302 may be associated with the input stage of the RF amplitude detector 300. For example, the diode bridge circuit 302 may be coupled to the RF input (e.g., RF power input) and DC setpoint input. The differential amplifier circuit 304 may be associated with a voltage comparison stage and/or output stage of the RF amplitude detector 300.

In some embodiments, the diode bridge circuit 302 is configured to rectify the RF input. For example, the diode bridge circuit 302 may be configured to rectify the positive peak of a RF input 305 and/or rectify the negative peak of the RF input 305. In some embodiments, the diode bridge circuit 302 comprises a plurality of diodes. In some embodiments, the differential amplifier circuit 304 comprises a plurality of operational amplifiers. One of more of the operational amplifiers may comprise a differential amplifier.

The diode bridge circuit 302 may comprise a first diode 306, a second diode 308, a third diode 310, and a fourth diode 312. Each of the first diode 306, second diode 308, third diode 310, and fourth diode 312 may be biased. For example, each of the of the first diode 306, second diode 308, third diode 310, and fourth diode 312 may be current biased diodes. The first diode 306 and the second diode 308 may be biased together. As shown in FIG. 3A, a negative terminal of the first diode 306 and a positive terminal of the second diode 308 may be coupled together at node 314, wherein a current flowing through the first diode 306 and the second diode 308 may be substantially the same. The first diode 306 and the second diode 308 may be coupled to the RF input 305. The first diode 306 may be configured to rectify the negative peak of the RF input 305 and the second diode 308 may be configured to rectify the positive peak of the RF input 305. In this regard, the RF signal path may include the first diode 306 and the second diode 308, wherein the first diode 306 and the second diode 308 are configured to rectify both negative and positive peaks of the RF signal path, respectively.

The first diode 306 and the second diode 308 may be coupled to the RF input 305 via a transformer 316. As shown in FIG. 3A, the RF input 305 may be coupled to the transformer 316. One or more capacitors and/or resistors may be coupled at one or more nodes between the RF input 305 and the transformer 316. As shown in FIG. 3A, the negative terminal of the first diode 306 and the positive terminal of the second diode 308 may be coupled to the transformer 316 at node 314. The diode bridge circuit 302 may define a negative branch and a positive branch, where the first diode 306 may be associated with the negative branch of the RF amplitude detector 300 and the second diode 308 may be associated with the positive branch of the RF amplitude detector 300.

The positive terminal of the first diode 306 may be coupled to an input terminal of a first operational amplifier 320 of the differential amplifier circuit 304. In the example embodiment shown in FIG. 3A, the positive terminal of the first diode 306 is coupled to a positive terminal of the first diode 306. In some embodiments, the positive terminal of the first diode 306 may be coupled to a negative terminal of the first diode 306. In some embodiments, as shown in FIG. 3A, a first capacitor 322 and a first resistor 324 are coupled to the first diode 306 between the positive terminal of the first diode 306 and an input terminal of the first operational amplifier 320. The first capacitor 322 and the first resistor 324 may be connected in parallel.

The negative terminal of the second diode 308 may be coupled to an input terminal of a second operational amplifier 326 of the differential amplifier circuit 304. In the example embodiment shown in FIG. 3A, the negative terminal of the second diode 308 is coupled to a positive terminal of the second diode 308. In some embodiments, the negative terminal of the second diode 308 may be coupled to a negative terminal of the second diode 308. In some embodiments, as shown in FIG. 3A, a second capacitor 328 and a second resistor 330 may be coupled between the negative terminal of the second diode 308 and an input terminal of the second operational amplifier 326 of the differential amplifier circuit 304. The second capacitor 328 and the second resistor 330 may be connected in parallel. In some embodiments, and as shown in FIG. 3A, the first capacitor 322 and the second capacitor 328 may have substantially the same capacitance. In some embodiments, and as shown in FIG. 3A, the first resistor 324 and the second resistor 330 may have substantially the same resistance. It should be understood that in some embodiments, the first capacitor 322 and the second capacitor 328 may have different capacitance and/or the first resistor 324 and the second resistor 330 may have different resistance.

As shown in FIG. 3A, a resistor 309 is coupled to the negative terminal of the first diode 306 and the positive terminal of the second diode 308. For example, a branch comprising the resistor 309 may be formed between the negative terminal of the first diode 306 and the positive terminal of the second diode 308. As shown in FIG. 3A, a branch comprising the node 314 where the transformer 316 is coupled to the first diode 306 and the second diode 308 may include one or more capacitors and/or resistors. The first operational amplifier 320 may be a differential amplifier. Alternatively or additionally, the first operational amplifier 320 may be a buffer amplifier. The second operational amplifier 326 may be a differential amplifier. Alternatively or additionally, the second operational amplifier 326 may be a buffer amplifier.

As shown in FIG. 3A, the third diode 310 is configured to be in the path of a negative DC setpoint input. The negative DC setpoint path may comprise one or more operational amplifiers, capacitors, and/or resistors. A positive DC setpoint input 307 may be coupled to an operational amplifier 334 configured as an inverter amplifier. The operational amplifier 334 (e.g., inverter amplifier) may be configured to receive the positive DC setpoint input 307 and output a negative DC setpoint. A negative terminal of the third diode 310 may be coupled to the operational amplifier 334. A resistor 336 may be coupled between the negative terminal of the third diode 310 and the output of the operational amplifier 334.

As shown in FIG. 3A, the positive terminal of the third diode 310 may be coupled to an input terminal of a third operational amplifier 340 of the differential amplifier circuit. In the example embodiment of FIG. 3A, the positive terminal of the third diode 310 is coupled to a positive input terminal of the third operational amplifier 340. In some embodiments, the positive terminal of the third diode 310 may be coupled to a negative input terminal of the third operational amplifier 340. A third resistor 338 may be coupled to the positive terminal of the third diode 310. For example, the third resistor 338 may be coupled at a node between the positive terminal of the third diode 310 and the positive input terminal of the third operational amplifier 340. One or more capacitors may be coupled the positive terminal of the third diode 310 (e.g., at one or more nodes between the positive terminal of the third diode 310 and the third operational amplifier 340.

As shown in FIG. 3A, the fourth diode 312 is configured to be in the path of a positive DC setpoint input. The positive DC setpoint path may comprise one or more operational amplifiers, capacitors, and/or resistors. As shown in FIG. 3A, a positive terminal of the fourth diode 312 may be coupled to an operational amplifier 342. A resistor 344 may be coupled between the positive terminal of the fourth diode 312 and the output terminal of the operational amplifier 342. As shown in FIG. 3A, the negative terminal of the fourth diode 312 may be coupled to an input terminal of a fourth operational amplifier 346 of the differential amplifier circuit. In the example embodiment of FIG. 3A, the negative terminal of the fourth diode 312 is coupled to a positive input terminal of the fourth operational amplifier 346. In some embodiments, the negative terminal of the fourth diode 312 may be coupled to a negative input terminal of the fourth operational amplifier 346.

A fourth resistor 348 may be coupled to the negative terminal of the fourth diode 312. For example, the fourth resistor 348 may be coupled at a node between the negative terminal of the fourth diode 312 and an input terminal of the fourth operational amplifier 346. One or more capacitors may be coupled to the negative terminal of the fourth diode 312 (e.g., at one or more nodes between the positive terminal of the fourth diode 312 and the fourth operational amplifier 346.

In some embodiments, the first resistor 324 and the third resistor 338 have a first predetermined resistance ratio. In some embodiments, the first resistor 324 and the third resistor 338 have a predetermined resistance ratio of 5 to 1. It should be understood, however that the first resistor 324 and the third resistor 338 may have a different resistance ratio in some embodiments. Alternatively or additionally, in some embodiments, the second resistor 330 and the fourth resistor 348 have a second predetermined resistance ratio. For example, in some embodiments, the second resistor 330 and the fourth resistor 348 may have a predetermined resistance ration of 5 to 1. It should be understood, however that the second resistor 330 and the fourth resistor 348 may have a different resistance ratio in some embodiments. In some embodiments, the first predetermined resistance ratio and the second predetermined resistance ratio are the same. In some embodiments, the first resistor 324 and the second resistor 330 have substantially the same resistance value. In some embodiments, the third resistor 338 and the fourth resistor have substantially the same resistance value. It should be understood that in some embodiments, the first resistor 324 and the second resistor 330 may have resistance values and/or the third resistor 338 and the fourth resistor have may have different resistance values. In some embodiments, at least a portion of the RF amplitude detector is temperature controlled to, for example reduce thermal drift associated with the RF amplitude circuit.

As shown in FIG. 3A, the output of each of the first operational amplifier 320, second operational amplifier 326, third operational amplifier 340, and fourth operational amplifier 346 may be coupled to a fifth operational amplifier 350 of the differential amplifier circuit at respective nodes. In some embodiments, the output of the first operational amplifier 320 is coupled to a negative input terminal of the fifth operational amplifier 350 and the output of the third operational amplifier 340 is coupled to a positive input terminal of the fifth operational amplifier 350. In some embodiments, the output of the second operational amplifier 326 is coupled to a positive input terminal of the fifth operational amplifier 350 and the output of the fourth operational amplifier 346 is coupled to a negative input terminal of the fifth operational amplifier 350. The differential amplifier circuit may be configured to compare the positive DC setpoint with the positive RF peak and compare the negative DC setpoint with the negative RF peak. For example, the difference amplifier circuit sums and/or subtracts the setpoints for the positive leg and the negative leg to output the error. In some embodiments, at least a portion of the RF amplitude detector 300 is temperature controlled to, for example, reduce the thermal drift.

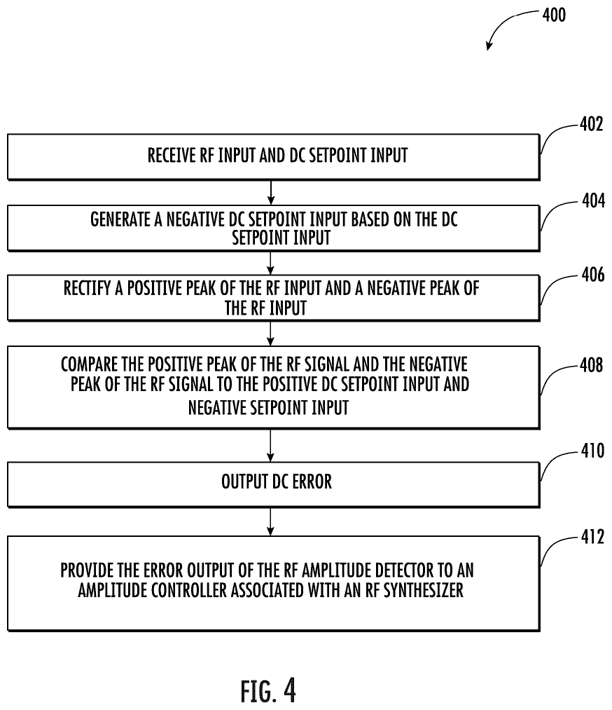

FIG. 4 illustrates a flowchart depicting example operations of an example RF amplitude detector in accordance with at least one example embodiment of the present disclosure. Specifically, FIG. 4 depicts an example process 400. In some embodiments, the example process 400 may be implemented by an example RF amplitude detector 300 described herein in connection with FIG. 3A. Although the example process 400 depicts a particular sequence of operations, the sequence may be altered without departing from the scope of the present disclosure. For example, some of the operations depicted may be performed in parallel or in a different sequence that does not materially affect the function of the process 400. In other examples, different components of an example device or system that implements the process 400 may perform functions at substantially the same time or in a specific sequence.

According to some examples, the method includes receiving RF input and DC setpoint input at operation 402. For example, the RF amplitude detector 300 may receive an RF input and DC setpoint input. In some embodiments, the DC setpoint input is a positive setpoint input. In some embodiments, the RF amplitude detector 300 receives the DC setpoint input from an amplitude controller (e.g., amplitude controller associated an RF synthesizer).

According to some examples, the method includes generating a negative DC setpoint input based on the DC setpoint input at operation 404. For example, the method includes converting a positive DC setpoint input into a negative DC setpoint input. For example, the method includes providing the positive DC setpoint input to an inverter amplifier of the RF amplitude detector. The inverter amplifier is configured to receive the positive DC setpoint input and output a negative DC setpoint.

According to some examples, the method includes rectifying a positive peak of the RF input and a negative peak of the RF input at operation 406. For example, the method includes rectifying a positive peak of the RF signal and a negative peak of the RF signal using a pair of diodes in the path of the RF signal at an input stage of the RF amplitude detector. The pair of diodes may be biased together with a positive terminal of one diode in the pair of diodes coupled to a negative terminal of the second diode in the pair of diodes and coupled to the RF input.

According to some examples, the method includes comparing the positive peak of the RF signal and the negative peak of the RF signal to the positive DC setpoint input and negative setpoint input at operation 408. For example, the method includes comparing the positive peak of the RF signal to the positive DC setpoint and comparing the negative peak of the RF signal to the negative setpoint. In some embodiments, the RF amplitude detector utilizes a differential amplifier circuit to compare the positive peak of the RF signal and the negative peak of the RF signal to the positive DC setpoint input and negative setpoint input. For example, the differential amplifier circuit may be configured to receive the positive and negative peaks of the rectified RF signal as well as the positive and negative DC setpoint input. The differential amplifier circuit may sum and/or subtract the positive and negative DC setpoint inputs with respect to the positive and negative peaks of the rectified RF signal to determiner a DC error.

According to some examples, the method includes outputting a DC error at operation 410. For example, the method includes outputting, based on the comparison of the positive peak of the RF signal and the negative peak of the RF signal to the positive DC setpoint input and negative setpoint input, outputting a DC error.

According to some examples, the method includes providing the error output of the RF amplitude detector to an amplitude controller associated with an RF synthesizer at operation 412. The amplitude controller may be configured to control a voltage attenuator that outputs the synthesized RF based on the error output received from the RF amplitude detector.

### Technical Advantages

Various embodiments provide technical solutions to the technical problems associated with RF synthesizers and RF amplitude detectors. In various embodiments, apparatuses, systems, and methods provide a stable RF amplitude detector having a diode bridge configuration at the input stage that enables a stable RF amplitude control. Some embodiments include a diode bridge that is balanced with itself in that the diode configuration includes a DC setpoint input that converts to a negative DC setpoint. Some embodiments, include a diode bridge configuration defining a positive branch and a negative branch that are coupled to a difference amplifier circuit. In some embodiments, the diode bridge rectifies the positive peak of the RF power and the negative peak of the RF power and then compares positive peak of the RF power and the negative peak of the RF power with the positive setpoint input and the negative setpoint input.

In some embodiments, a portion of the diodes are biased together, so the current is identical through the diodes for the RF power level. In some embodiments, the difference amplifier circuit sums and/or subtracts the setpoints for the positive leg and the negative leg to output the error. In this regard, embodiments of the present disclosure include a specially configured diode bridge circuit at the input stage that enables stable RF amplitude control. In this regard, embodiments of the present disclosure allow for RF synthesizer applications (e.g., radial gates, and/or the like) that require stable RF amplitude control. In some embodiments, the circuit is temperature controlled to reduce the thermal drift of the circuit.

### Exemplary Controller

In various embodiments, an atomic object confinement apparatus 120 is incorporated into a system (e.g., a quantum computer 110) comprising a controller 30. In various embodiments, the controller 30 is configured to control various elements of the system (e.g., quantum computer 110). For example, the controller 30 may be configured to control the voltage sources 50, a cryogenic system and/or vacuum system controlling the temperature and pressure within the cryogenic and/or vacuum chamber 40, manipulation sources 60, cooling system, and/or other systems controlling the environmental conditions (e.g., temperature, humidity, pressure, and/or the like) within the cryogenic and/or vacuum chamber 40 and/or configured to manipulate and/or cause a controlled evolution of quantum states of one or more atomic objects confined by the atomic object confinement apparatus 120. In various embodiments, the controller 30 may be configured to receive signals from one or more optics collection systems.

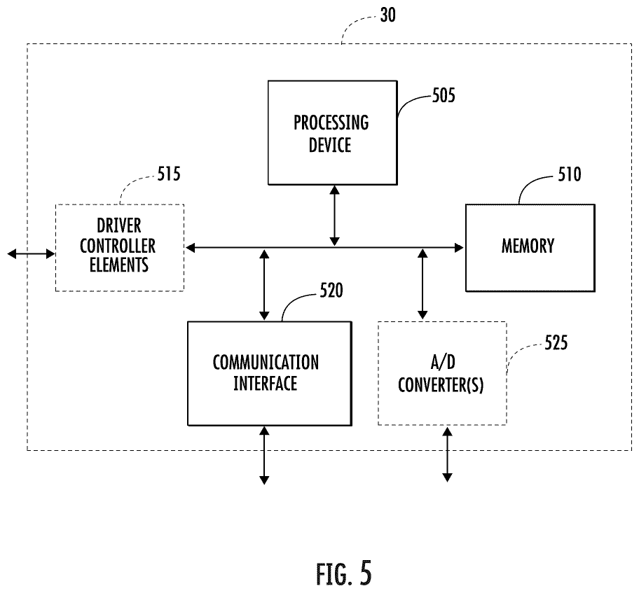

As shown in FIG. 5, in various embodiments, the controller 30 may comprise various controller elements including processing elements 505 (e.g., processing device), memory 510, driver controller elements 515, a communication interface 520, analog-digital converter elements 525, and/or the like. For example, the processing elements 505 may comprise programmable logic devices (CPLDs), microprocessors, coprocessing entities, application-specific instruction-set processors (ASIPs), integrated circuits, application specific integrated circuits (ASICs), field programmable gate arrays (FPGAs), programmable logic arrays (PLAs), hardware accelerators, other processing devices and/or circuitry, and/or the like. and/or controllers. The term circuitry may refer to an entirely hardware embodiment or a combination of hardware and computer program products. In an example embodiment, the processing element 505 of the controller 30 comprises a clock and/or is in communication with a clock.

For example, the memory 510 may comprise non-transitory memory such as volatile and/or non-volatile memory storage such as one or more of as hard disks, ROM, PROM, EPROM, EEPROM, flash memory, MMCs, SD memory cards, Memory Sticks, CBRAM, PRAM, FeRAM, RRAM, SONOS, racetrack memory, RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. In various embodiments, the memory 510 may store a queue of commands to be executed to cause a quantum algorithm and/or circuit to be executed (e.g., an executable queue), qubit records corresponding the qubits of quantum computer (e.g., in a qubit record data store, qubit record database, qubit record table, and/or the like), a calibration table, computer program code (e.g., in a one or more computer languages, specialized controller language(s), and/or the like), and/or the like. In an example embodiment, execution of at least a portion of the computer program code stored in the memory 510 (e.g., by a processing element 505) causes the controller 30 to perform one or more steps, operations, processes, procedures and/or the like described herein for providing manipulation signals to atomic object positions and/or collecting, detecting, capturing, and/or measuring indications of emitted signals emitted by atomic objects located at corresponding atomic object positions of the atomic object confinement apparatus 120.

In various embodiments, the driver controller elements 515 may include one or more drivers and/or controller elements each configured to control one or more drivers. In various embodiments, the driver controller elements 515 may comprise drivers and/or driver controllers. For example, the driver controllers may be configured to cause one or more corresponding drivers to be operated in accordance with executable instructions, commands, and/or the like scheduled and executed by the controller 30 (e.g., by the processing element 505). In various embodiments, the driver controller elements 515 may enable the controller 30 to operate a voltage sources 50, manipulation sources 60, cooling system, and/or the like. In various embodiments, the drivers may be laser drivers configured to operate one or manipulation sources 60 to generate manipulation signals; vacuum component drivers; drivers for controlling the flow of current and/or voltage applied to electrodes used for maintaining and/or controlling the trapping potential of the atomic object confinement apparatus 120 (and/or other drivers for providing driver action sequences to potential generating elements of the atomic object confinement apparatus); cryogenic and/or vacuum system component drivers; cooling system drivers, and/or the like. In various embodiments, the controller 30 comprises means for communicating and/or receiving signals from one or more optical receiver components (e.g., photodetectors of the optics collection system). For example, the controller 30 may comprise one or more analog-digital converter elements 525 configured to receive signals from one or more optical receiver components (e.g., a photodetector of the optics collection system), calibration sensors, and/or the like.

In various embodiments, the controller 30 may comprise a communication interface 520 for interfacing and/or communicating with a computing entity 10. For example, the controller 30 may comprise a communication interface 520 for receiving executable instructions, command sets, and/or the like from the computing entity 10 and providing output received from the quantum computer 110 (e.g., from an optical collection system) and/or the result of a processing the output to the computing entity 10. In various embodiments, the computing entity 10 and the controller 30 may communicate via a direct wired and/or wireless connection and/or via one or more wired and/or wireless networks 20.

### Exemplary Computing Entity

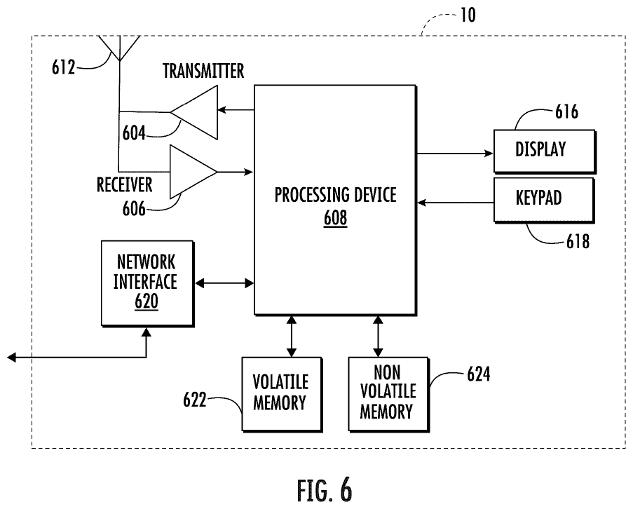

FIG. 6 provides an illustrative schematic representative of an example computing entity 10 that can be used in conjunction with embodiments of the present invention. In various embodiments, a computing entity 10 is configured to allow a user to provide input to the quantum computer 110 (e.g., via a user interface of the computing entity 10) and receive, display, analyze, and/or the like output from the quantum computer 110.

As shown in FIG. 6, a computing entity 10 can include an antenna 612, a transmitter 604 (e.g., radio), a receiver 606 (e.g., radio), and a processing element 608 (e.g., processing device) that provides signals to and receives signals from the transmitter 604 and receiver 606, respectively. The signals provided to and received from the transmitter 604 and the receiver 606, respectively, may include signaling information/data in accordance with an air interface standard of applicable wireless systems to communicate with various entities, such as a controller 30, other computing entities 10, and/or the like. In this regard, the computing entity 10 may be capable of operating with one or more air interface standards, communication protocols, modulation types, and access types. For example, the computing entity 10 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 10 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1X (1xRTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The computing entity 10 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the computing entity 10 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The computing entity 10 can also download changes, add-ons, and updates, for instance, to its firmware, software (e.g., including executable instructions, applications, program modules), and operating system.

In various embodiments, the computing entity 10 may comprise a network interface 620 for interfacing and/or communicating with the controller 30, for example. For example, the computing entity 10 may comprise a network interface 620 for providing executable instructions, command sets, and/or the like for receipt by the controller 30 and/or receiving output and/or the result of a processing the output provided by the quantum computer 110. In various embodiments, the computing entity 10 and the controller 30 may communicate via a direct wired and/or wireless connection and/or via one or more wired and/or wireless networks 20.

The computing entity 10 may also comprise a user interface device comprising one or more user input/output interfaces (e.g., a display 616 and/or speaker/speaker driver coupled to a processing element 608 and a touch screen, keyboard, mouse, and/or microphone coupled to a processing element 608). For instance, the user output interface may be configured to provide an application, browser, user interface, interface, dashboard, screen, webpage, page, and/or similar words used herein interchangeably executing on and/or accessible via the computing entity 10 to cause display or audible presentation of information/data and for interaction therewith via one or more user input interfaces. The user input interface can comprise any of a number of devices allowing the computing entity 10 to receive data, such as a keypad 618 (hard or soft), a touch display, voice/speech or motion interfaces, scanners, readers, or other input device. In embodiments including a keypad 618, the keypad 618 can include (or cause display of) the conventional numeric (0-9) and related keys (#, *), and other keys used for operating the computing entity 10 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 10 can collect information/data, user interaction/input, and/or the like.

The computing entity 10 can also include volatile storage or memory 622 and/or non-volatile storage or memory 624, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 10.

### Conclusion

Many modifications and other embodiments of the disclosure set forth herein will come to mind to one skilled in the art to which this disclosure pertains having the benefit of the teachings presented in the foregoing description and the associated drawings. Therefore, it is to be understood that the embodiments are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

Further, while this detailed description has set forth some embodiments of the present disclosure, the appended claims may cover other embodiments of the present disclosure which differ from the described embodiments according to various modifications and improvements. For example, while the illustrated embodiment depicts certain values for various components of the example, RF amplitude detector and example RF synthesizer, it should be understood that these are intended to be non-limiting and the values for the components may be different in other embodiments without departing from the scope of the present disclosure.

1. An RF amplitude detector comprising:
a diode bridge circuit comprising a plurality of diodes, wherein at least a portion of the plurality of diodes are biased together and configured to rectify a positive peak of an RF input and a negative peak of the RF input; and
a differential amplifier circuit comprising a plurality of differential amplifiers, the differential amplifier circuit configured to: (a) compare the positive peak of the RF input rectified by the diode bridge circuit to a positive DC setpoint input, (b) compare the negative peak of the RF input rectified by the diode bridge circuit to a negative DC setpoint input, and (c) output an error value.

2. The RF amplitude detector of claim 1, wherein the diode bridge circuit comprises:
a first diode having a negative terminal coupled to the RF input via a transformer and a positive terminal coupled to a first amplifier of the differential amplifier circuit;
a second diode having a positive terminal coupled to the RF input via the transformer and a negative terminal coupled to a second amplifier of the differential amplifier;
a third diode in a path of the negative DC setpoint input; and
a fourth diode in a path of the positive DC setpoint input.

3. The RF amplitude detector of claim 2, wherein the negative terminal of the first diode is coupled to the positive terminal of the second diode.

4. The RF amplitude detector of claim 2, further comprising an inverter amplifier configured to output the negative DC setpoint input based on the positive DC setpoint input.

5. The RF amplitude detector of claim 2, wherein:
a first resistor is coupled between the negative terminal of the first diode and the first amplifier;
a second resistor is coupled between the negative terminal of the second diode and the second amplifier;
a third resistor is coupled between a positive terminal of the third diode and a third amplifier; and
a fourth resistor is coupled between a negative terminal of the fourth diode and the fourth resistor.

6. The RF amplitude detector of claim 5, wherein:
the first resistor and the third resistor have a first predetermined resistance ratio; and
the second resistor and the fourth resistor have a second predetermined resistance ratio.

7. The RF amplitude detector of claim 6, wherein the first predetermined resistance ratio and the second predetermined resistance ratio are the same.

8. The RF amplitude detector of claim 5, wherein the first resistor and the second resistor have substantially the same resistance value.

9. The RF amplitude detector of claim 5, wherein the third resistor and fourth resistor have substantially the same resistance value.

10. The RF amplitude detector of claim 1, wherein at least a portion of the RF amplitude detector is temperature controlled.

11. An RF synthesizer comprising:
an RF amplitude detector, the RF amplitude detector comprising:
a diode bridge circuit comprising a plurality of diodes, wherein at least a portion of the plurality of diodes are biased together and configured to rectify a positive peak of an RF input and a negative peak of the RF input; and
a differential amplifier circuit comprising a plurality of differential amplifiers, the differential amplifier circuit configured to: (a) compare the positive peak of the RF input rectified by the diode bridge circuit to a positive DC setpoint input, (b) compare the negative peak of the RF input rectified by the diode bridge circuit to a negative DC setpoint input, and (c) output an error value.

12. The RF synthesizer of claim 11, wherein the diode bridge circuit comprises:
a first diode having a negative terminal coupled to the RF input via a transformer and a positive terminal coupled to a first amplifier of the differential amplifier circuit;
a second diode having a positive terminal coupled to the RF input via the transformer and a negative terminal coupled to a second amplifier of the differential amplifier;
a third diode in a path of the negative DC setpoint input; and
a fourth diode in a path of the positive DC setpoint input.

13. The RF synthesizer of claim 12, wherein the negative terminal of the first diode is coupled to the positive terminal of the second diode.

14. The RF synthesizer of claim 12, wherein the RF amplitude detector further comprises an inverter amplifier configured to output the negative DC setpoint input based on the positive Dc setpoint input.

15. The RF synthesizer of claim 12, wherein:
a first resistor is coupled between the negative terminal of the first diode and the first amplifier;
a second resistor is coupled between the negative terminal of the second diode and the second amplifier;
a third resistor is coupled between a positive terminal of the third diode and a third amplifier; and
a fourth resistor is coupled between a negative terminal of the fourth diode and the fourth resistor.

16. The RF synthesizer of claim 15, wherein:
the first resistor and the third resistor have a first predetermined resistance ratio; and
the second resistor and fourth resistor have a second predetermined resistance ratio.

17. The amplitude synthesizer of claim 16, wherein the first predetermined resistance ratio and the second predetermined resistance ratio are the same.

18. The RF synthesizer of claim 15, wherein the first resistor and the second resistor have substantially the same resistance value.

19. The RF synthesizer of claim 15, wherein the third resistor and fourth resistor have substantially the same resistance value.

20. The RF synthesizer of claim 11, wherein at least a portion of the RF amplitude detector is temperature controlled.
